(19) United States
(12) Patent Application Publication
(10) Pub. No.: US 2009/0283302 A1
(43) Pub. Date: Nov. 19, 2009

(54) Printed circuit board and manufacturing method thereof

(75) Inventors: Seok-Kyu Lee, Suwon-si (KR); Shuhichi Okabe, Suwon (KR); Seung-Hyun Cho, Seoul (KR); Jae-Joon Lee, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/318,748

(22) Filed: Jan. 7, 2009

(30) Foreign Application Priority Data
May 13, 2008 (KR) 10-2008-0043929

(51) Int. Cl. H05K 1/00; H05K 3/46; H05K 3/22

(52) U.S. Cl. 174/255; 427/97.1; 156/247; 156/73.1

(57) ABSTRACT

Disclosed are a printed circuit board and a manufacturing method thereof. The printed circuit board in accordance with the present invention includes: a circuit laminate, a solder resist laminated on the circuit laminate, a metal support layer formed on the solder resist, a stiffener formed on the metal support layer.

### CROSS-REFERENCE TO RELATED APPLICATIONS

This application claims the benefit of Korean Patent Application No. 10-2008-0043929, filed with the Korean Intellectual Property Office on May 13, 2008, the disclosure of which is incorporated herein by reference in its entirety.

### BACKGROUND

1. Technical Field

The present invention relates to a printed circuit board and a manufacturing method thereof.

2. Description of the Related Art

Due to high performance and minimization of electronic devices, the number of semiconductor chip terminals is being remarkably increased. For this reason, the core of a FC-BGA substrate that is used as a package substrate for improving a signal transfer speed is being thinned. As the core is thinned, a loop inductance has a smaller value. Accordingly, the signal transfer speed can be improved.

If there is no core or the thickness of the core is thinner, the electric property is more improved. But, as the thickness of the substrate becomes thinner, a warpage problem occurs during the process of products. Therefore, the process difficult to perform and much time required for the process cause a lead time to increase. Additionally, there is a problem to produce much inferior goods unsuitable for the warpage specification of the final FC-BGA substrate.

Minimizing and thinning of the electronic components in the printed circuit board indispensably require thin thickness. Thinning of the substrate caused by high performance the electronic components is being increasingly required. The thin printed circuit board becomes so thin as to have its structure vulnerable to the warpage, and may be warped by residual stress generated from a repetitive thermal process as well.

### SUMMARY

The present invention provides a printed circuit board capable of raising the warpage resistance of a thin printed circuit board and maximally preventing the occurrence of warpage even in a thermal process performed at a high temperature during bonding a solder ball or a solder bump to the printed circuit board, and a manufacturing method thereof

An aspect of the present invention features a manufacturing method of a printed circuit board. The method in accordance with an embodiment of the present invention can include: forming a first solder resist; forming a circuit laminate on-the first solder resist; forming a second solder resist on the circuit laminate; forming a metal support layer on the second solder resist; and forming a stiffener on the metal support layer.

Before the forming of the first solder resist, providing a carrier, providing a carrier is further included. The first solder resist can be formed on one side or both sides of the carrier.

After the forming of the metal support layer on the second solder resist, separating the first solder resist, the circuit laminate, the second solder resist and the metal support layer from the carrier can be further performed.

The separating of the first solder resist, the circuit laminate, the second solder resist and the metal support layer from the carrier can be performed by cutting a part of the first solder resist, the circuit laminate, the second solder resist and the metal support layer through a routing process.

The circuit laminate can include a circuit pattern layer and an insulation layer.

The stiffener is made of a metallic material, and the forming of the stiffener on the metal support layer can be performed by bonding the stiffener to the metal support layer through an ultrasonic bonding method.

The forming of the metal support layer on the second solder resist can include forming roughness on the surface of the second solder resist, forming a seed layer on the second solder resist through electroless plating; and forming a conductive material on the seed layer through electrolytic plating.

After the forming of the metal support layer on the second solder resist, selectively removing a part of the metal support layer can be further included.

The selectively removing of a part of the metal support layer can be performed by laminating a photosensitive material on the metal support layer, forming an etching resist on the metal support layer by selectively exposing the photosensitive material to light and developing the photosensitive material, and etching the metal support layer.

The carrier can include a substrate and a separation layer covering a part of the substrate. The substrate is a metal laminated plate and the separation layer can be made of a material including a release material.

After the separating of the first solder resist, the circuit laminate, the second solder resist and the metal support layer from the carrier, selectively opening the first solder resist and the second solder resist, and bonding a solder ball to the circuit laminate exposed by opening the first solder resist and the second solder resist can be further performed.

The selectively opening of the first solder resist and the second solder resist can be performed by irradiating a laser beam to a part of the first solder resist and the second solder resist.

Another aspect of the present invention features a printed circuit board. The printed circuit board in accordance with an embodiment of the present invention can include: a circuit laminate; a solder resist laminated on the circuit laminate; a metal support layer formed on the solder resist; and a stiffener formed on the metal support layer.

The circuit laminate can include a circuit pattern layer and an insulation layer.

The solder resist can include a first solder resist laminated on one side of the circuit laminate, and a second solder resist laminated on the other side of the circuit laminate. The metal support layer can be formed on the second solder resist.

The stiffener can be made of a material including a metallic material. The stiffener can be bonded to the metal support layer by performing an ultrasonic bonding method. A part of the stiffener can be opened in correspondence to a position where the electronic component is to be mounted. A height of an upper surface of the stiffener corresponds to a height of an upper surface of the electronic component.

A part of the metal support layer and a part of the solder resist can be opened in correspondence to a position where the electronic component is to be mounted.

Meanwhile, the stiffener can be configured to cover a part of the metal support layer.

The circuit laminate can be electronically connected to the electronic component through a solder ball bonded to the circuit laminate.

### BRIEF DESCRIPTION OF THE DRAWINGS

FIG. 1 illustrates a manufacturing method of a printed circuit board according to an embodiment of the present invention.

FIGS. 2 to 16 illustrate a manufacturing process of a printed circuit board according to an embodiment of the present invention.

FIG. 17 illustrates a cross sectional view of a printed circuit board according to an embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention. In the following description of the present invention, the detailed description of known technologies incorporated herein will be omitted when it may make the subject matter unclear.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, a printed circuit board and a manufacturing method thereof according to the present invention will be described in detail with reference to the accompanying drawings. In description with reference to the accompanying drawings, the same reference numerals will be assigned to the same or corresponding elements, and repetitive descriptions thereof will be omitted.

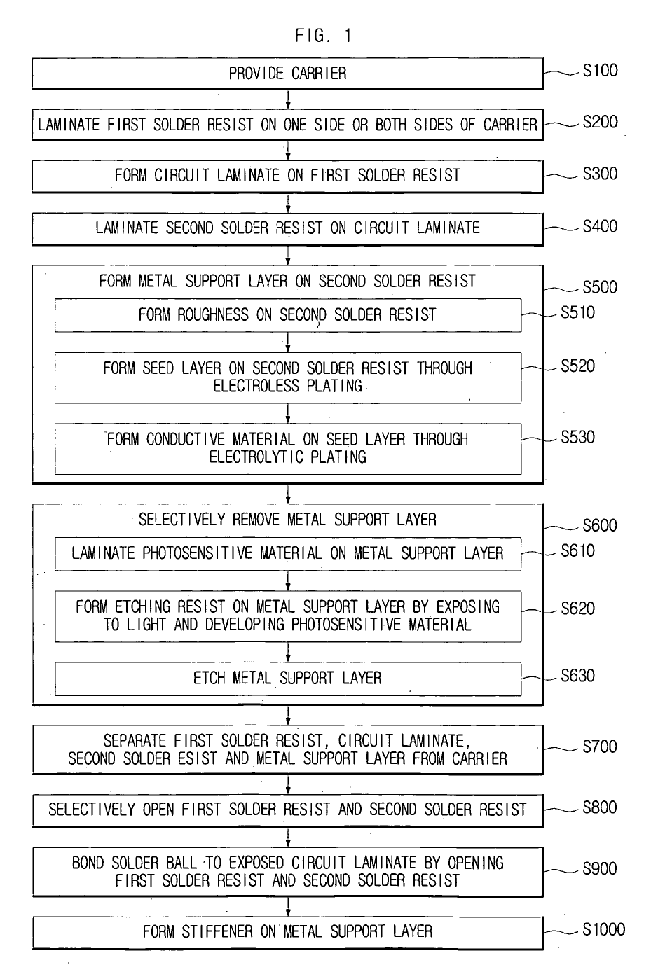

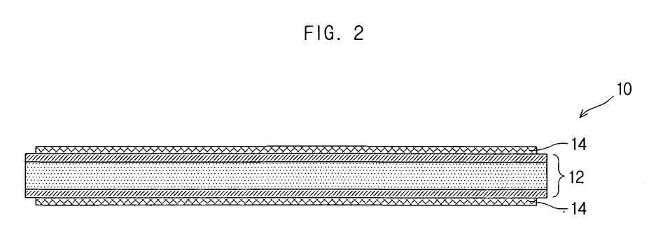

FIG. 1 illustrates a manufacturing method of a printed circuit board according to an embodiment of the present invention. FIGS. 2 to 16 illustrate a manufacturing process of a printed circuit board according to an embodiment of the present invention. Referring to FIGS. 2 to 16, illustrated are a carrier 10, a substrate 12, a separation layer 14, a first solder resist 20, a second solder resist 22, a circuit laminate 30, a circuit pattern layer 32, a circuit pattern 32a, a pad 32b, an insulation layer 34, an insulating material 36, a via 38, a metal support layer 40, a seed layer 42, an etching resist 46, a stiffener 50 and a solder ball 60.

According to an embodiment of the present invention, a carrier 10 is provided as shown in FIG. 2 (S100).

The carrier 10 is a base for forming a substrate, and supports intermediate products for forming a substrate during the process of transferring process equipments. In the manufacturing process of a thin coreless printed circuit board without a core, a transfer process and a lamination process are performed by using the carrier.

According to the embodiment of the present invention, the carrier 10 can be configured by a substrate 12 and a separation layer 14 covering a part of the substrate 12.

The substrate 12 performs a function of a support causing a solder resist laminated on the carrier 10 and a circuit laminate 30 not to be warped during the transferring and process. Therefore, it is more advantageous that there is low thermal expansion coefficient difference between the substrate 12 and the material laminated on the carrier. According to the embodiment of the present invention, the substrate can be a metal laminated plate made of a metal clad laminated insulating material. The substrate 12 can be made of a generally used copper clad laminate (CCL). Besides, a metal laminated plate suitable for the property of a process of laminating various materials can be used as the substrate 12.

As shown in FIG. 2, the separation layer 14 is not configured to cover the entire surface of the substrate 12. After the lamination process to be later described, the separation layer 14 performs a function of easily separating the carrier 10 from the circuit laminate 30 and the solder resist 20.

According to the embodiment of the present invention, the solder resist 20 is laminated on the carrier 10. The solder resist and the circuit laminate 30 being laminated thereon are separated from the carrier during the process to be described below. Therefore, according to an embodiment of the present invention, the separation layer 14 can be made of a material including a release material which allows the solder resist to easily separate from the carrier.

The release material can be a release film formed on the metal laminated plate, and can be also formed on the metal laminated plate in various shapes within the scope of the object of the present invention. The release material covers a part of the metal laminated plate. This intends to prevent a first solder resist 20 to be later described from randomly separating from the carrier 10 during the transfer and lamination process.

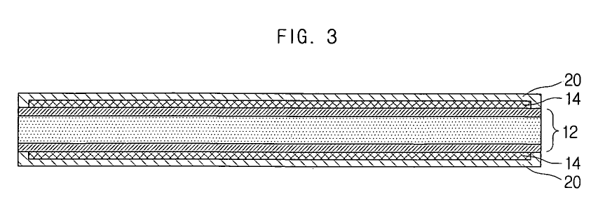

Then, the first solder resist 20 is formed on either one or both sides of the carrier 10 as shown in FIG. 3 (S200).

The first solder resist 20 covers the substrate 12 and the separation layer 14 which are in the carrier 10. Since the separation layer covers a part of the substrate 12, the first solder resist can bond to the substrate on the area not covered by the separation layer. Because the first solder resist bonds to the surface of the substrate 12 in the carrier, it is possible to fix the relative positions of the carrier and the first solder resist.

The first solder resist 20 can be formed by laminating a dry film type solder resist (DFSR) such that the substrate 12 and the separation layer 14 are covered. The first solder resist can be also formed by applying a solder resist ink.

According to the embodiment of the present invention, the first solder resist 20 and the substrate 12 of the carrier 10 include the release material interposed therebetween and they come in contact with on their external parts.

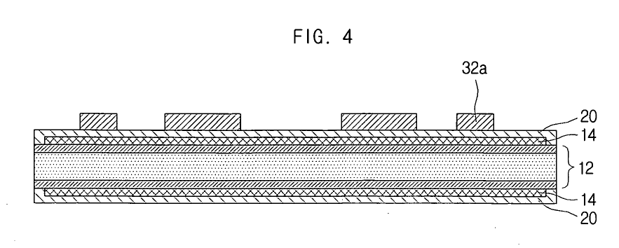

Then, the circuit laminate 30 is formed on the first solder resist 20 (S300). The forming of the circuit laminate will be described with reference to FIGS. 4 to 6.

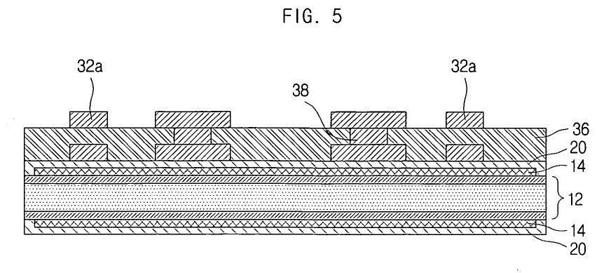

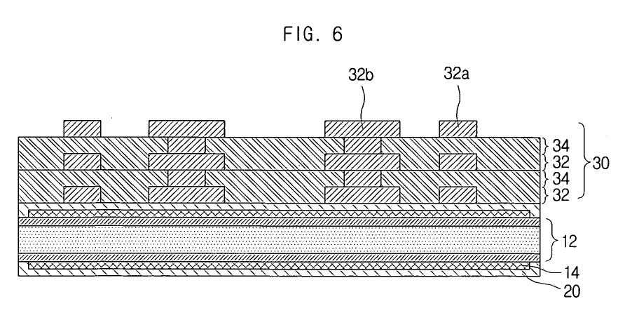

Referring to FIG. 4, the circuit pattern 32a is formed on the first solder resist 20. As shown in FIG. 5, the insulating material 36 is laminated, which insulates the circuit pattern 32a. The circuit pattern 32a and a via 38 connecting an upper and lower circuit patterns are formed through a semi additive process. The circuit laminate can be formed by repeating the process of FIGS. 4 and 5, which includes at least one circuit pattern layer 32 and at least one insulation layer 34 as shown in FIG. 6.

The circuit laminate 30 according to an embodiment of the present invention can be built up on the first solder resist 20 through the following process. A metal layer is formed on one side of the first solder resist by electroless plating. The metal layer is patterned in the predetermined shape such that the circuit pattern 32a. is formed as shown in FIG. 4. The formed circuit pattern includes the insulating material laminated thereon. A via hole is formed by removing parts corresponding to the circuit pattern 32a in the insulating material 36 by means of a laser drill and so on. The via 38 and the circuit pattern 32a are formed by filling the via hole with metal, thereby forming one circuit pattern layer 32 and one insulation layer 34. Made can be the circuit laminate 30 including several circuit pattern layers and insulation layers by repeating the process mentioned above.

In the description and the drawings of the present invention, a process of forming the circuit laminate 30 on the first solder resist 20 can be performed on both sides of the carrier 10 as well as on one side. Consequently, same two (or two same?) coreless printed circuit boards can be manufactured by removing the carrier during the process of separating the carrier.

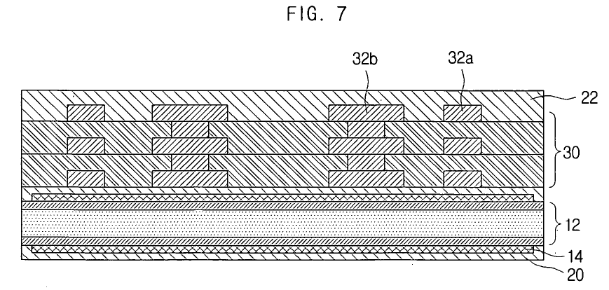

Subsequently, a second solder resist 22 is formed on the circuit laminate as shown in FIG. 7 (S400).

The second solder resist 22 can be formed by laminating a dry film type solder resist (DFSR) such that the circuit pattern 32a and the insulating material 36 that are exposed on the upper surface of the circuit laminate 30 are covered. The second solder resist can be also formed by applying a solder resist ink.

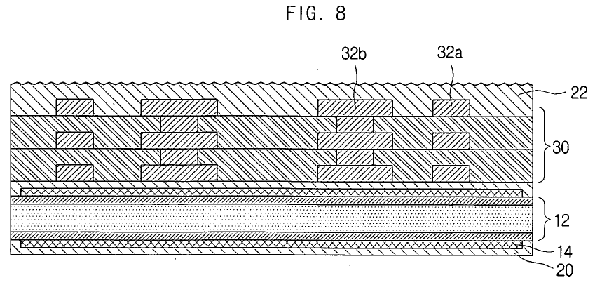

As shown in FIGS. 8 to 10, a metal support layer 40 is formed on the second solder resist 22 (S500).

According to an embodiment of the present invention, the surface roughness can be formed on the second solder resist such that a seed layer 42 can be well formed, which is for forming the metal support layer 40 on the second solder resist 22. During the performing of the electroless plating on the surface of the second solder resist, a desmear process as one of surface treatment processes can be performed in order to successfully bond the seed layer to the upper part of the second solder resist.

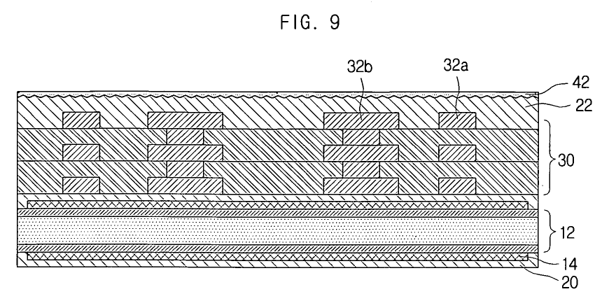

Thereafter, as shown in FIG. 9, the seed layer 42 is formed on the second solder resist 22 through the electroless plating. The seed layer has a thin thickness through an electroless chemical copper plating. The seed layer functions as a base layer for forming the conductive material during an electrolytic plating process to be described below.

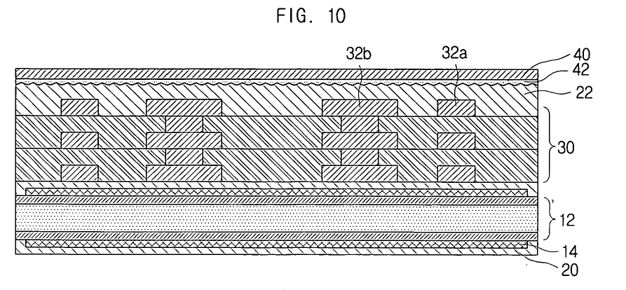

Then, the conductive material is formed on the seed layer 42 through the electrolytic plating process as shown in FIG. 10. During the electrolytic plating process, the seed layer 42 has a plating material formed thereon. The conductive material having a desired thickness can be formed by performing the electrolytic plating process for a certain length of time.

The conductive material formed on the seed layer 42 corresponds to the metal support layer 40 and prevents a thin coreless substrate from being warped after the carrier 10 separates from the thin coreless substrate. That is, since the coreless substrate does not include a core layer, the substrate may have a relatively low rigidity. Therefore, the metal support layer is formed outside the substrate so as to provide an additional rigidity to the substrate.

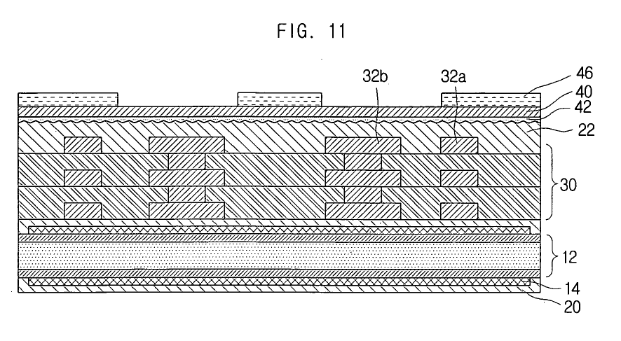

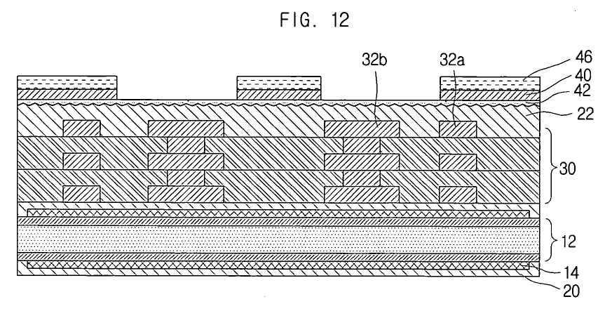

Next, parts of the metal support layer 40 are selectively removed as shown in FIGS. 11 and 12 (S600). While covering the second solder resist 22, the metal support layer 40 can be partly removed at a position corresponding to both a position of an electronic component mounted in the printed circuit board and a position of the electronic component bonding to the printed circuit board. According to an embodiment of the present invention, a solder ball 60 can be bonded to the printed circuit board at the positions of the parts of the metal support layer 40 which has been selectively removed. The electronic component can be electrically connected to the printed circuit board through the solder ball 60.

A photosensitive material is laminated on the metal support layer such that a part of the metal support layer is opened by selectively removing the metal support layer 40 (S610). Then, the photosensitive material is selectively exposed to light and developed so that an etching resist 46 can be formed on- the metal support layer as shown in FIG. 11 (S620). According to the embodiment of the present invention, exposed is only the etching resist corresponding to the metal support layer to be removed.

Subsequently, the metal support layer 40 not covered by the etching resist 46 is etched by providing etching solution as shown in FIG. 12 (S630). The second solder resist 22 can be partly exposed by etching a part of the metal support layer.

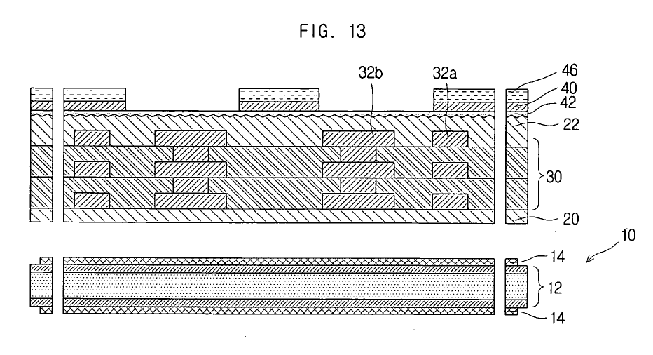

As shown in FIG. 13, the carrier 10 is separated from the first solder resist 20, the circuit laminate 30, the second solder resist 22 and the metal support layer 40 (S700).

The carrier 10 is used only in the process of manufacturing the substrate and is not included in the final product of the coreless printed circuit board. Accordingly, the carrier is separated from the first solder resist 20, the circuit laminate 30, the second solder resist 22 and the metal support layer 40 in the process.

As described above, the separation layer 14 of the carrier 10 can be made of a release material and covers a part of the substrate 12 of the carrier. The first solder resist 20 is bonded to the substrate 12 of the carrier at the position of the separation layer having no release material formed thereon.

A part of the first solder resist 20, the circuit laminate 30, the second solder resist 22 and the metal support layer 40 are cut by performing a routing process as shown in FIG. 13. In this case, the carrier can be separated by cutting the part on which the first solder resist 20 has been bonded to the carrier 10.

According to the embodiment of the present invention, an interface providing an bonding force between the first solder resist 20 and the carrier 10 is limited to an bonding force between the first solder resist 20 and the separation layer of the carrier 10, so that the carrier can be easily separated. Through the routing process, the first solder resist is placed only on the separation layer 14 of the carrier.

The separation process above features that it is to use only the part of the first solder resist 20, having no direct bond to the substrate 12 of the carrier 10. By performing the routing process as shown in FIG. 13, the carrier can be easily separated from the first solder resist 20 bonding to the separation layer 14 made of the release material, the circuit laminate 30 laminated on the first solder resist, the second solder resist 22 and the metal support layer 40.

In the embodiment of the present invention, while even the carrier 10 has been completely cut, it is possible to reuse the substrate 12 of the carrier by controlling the depth of cutting in the routing process not to reach the substrate 12 of the carrier 10, if necessary.

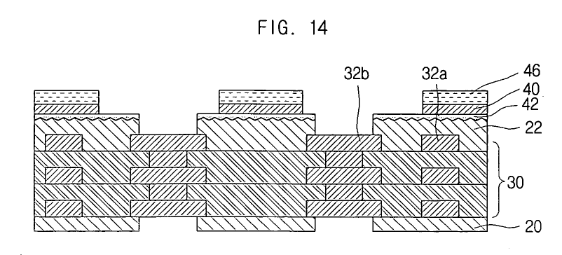

As shown in FIG. 14, the first solder resist 20 and the second solder resist 22 are selectively opened (S800). The second solder resist 22 has been partly exposed in the selective removing of the metal support layer 40. That is, a part of the metal support layer is in an open state in correspondence to the position of the electronic component mounted on the printed circuit board.

The second solder resist 22 exposed at a position of the selectively removed metal support layer 40 is selectively opened. The circuit pattern 32a and the pad 32b of the circuit laminate 30 can be exposed to the outside by opening the second solder resist. The printed circuit board and the electronic component can be electrically connected to each other through the solder ball 60 bonded to the exposed circuit pattern and the pad.

The first solder resist 20 can be a side facing a main board having the printed circuit board mounted thereon. Accordingly, the first solder resist is selectively opened and the solder ball 60 is bonded to the circuit pattern 32a and the pad 32b exposed by the opening, so that the printed circuit board can be connected to an external substrate.

Meanwhile, as shown in FIG. 14, the process of selectively opening the first solder resist 20 and the second solder resist 22 can be performed by irradiating a laser beam to a designed for opening the positions of the first solder resist 20 and the second solder resist 22. According to the embodiment of the present invention, after the carrier 10 is separated, the first solder resist and the second solder resist are in a cured state. Therefore, the first solder resist and the second solder resist can be selectively opened by partly irradiating the laser beam to the cured first solder resist and second solder resist.

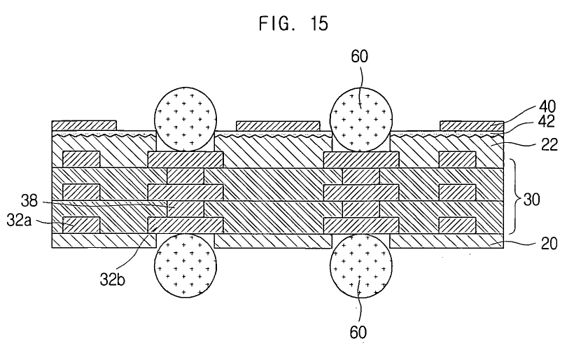

After that, the solder ball 60 is bonded to the pad 32b exposed to the outside as shown in FIG. 15 (S900). In the side on which the electronic component is mounted, the solder ball is a through means between the electronic component and the printed circuit board. In the side having the printed circuit board being mounted on the main board, the solder ball is a through means between the main board and the printed circuit board.

After the first solder resist 20 and the second solder resist 22 are opened and before the solder ball 60 is bonded to the pad 32b, the surface of pad can be treated by nickel-plating/gold plating. An organic solderability preservative (OSP) process can be also used to treat the surface.

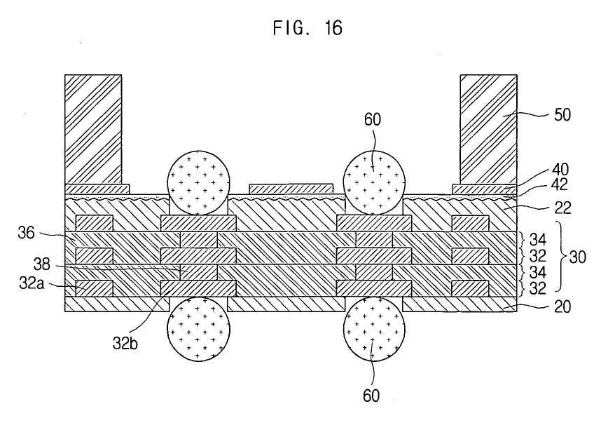

Next, as shown in FIG. 16, a stiffener 50 is formed on the metal support layer 40 (S1000). The stiffener provides rigidity to the coreless printed circuit board. The stiffener can include a metallic material having rigidity. The stiffener is made of a metallic material. An ultrasonic bonding process can be performed so as to bond the stiffener to the metal support layer formed of the conductive materials during the plating process.

As shown in FIG. 16, it is possible to bond the metal stiffener having rigidity to the metal support layer 40 by performing the ultrasonic bonding process. The stiffener may have a material like a metal intermediate support. The stiffener can include a material including copper or other metals such as SUS and Ni. According to an ultrasonic bonding principle, since materials having the same property best bond to each other, it is desirable to use the metal support layer and the stiffener which are made of copper.

The ultrasonic bonding principle uses physical interference between metal structures. According to the embodiment of the present invention, it is possible to bond the stiffener 50 to the metal support layer 40 for a short time with reliability.

It may be possible to bond the stiffener 50 through the ultrasonic bonding for within several seconds. Therefore, through use of the ultrasonic bonding method, it is possible to perform a large amount of tasks for very short time as compared with a stiffener bonding process that uses a polymer resin.

As shown in FIG. 16, a part of the stiffener 50 is opened in correspondence to the position of the electronic component to be mounted. The thickness of the entire package board module can be reduced by mounting the electronic component on the position of the open part of the stiffener.

A printed circuit board having no occurrence of warpage during the manufacturing process can be provided through the method of manufacturing the printed circuit board described with reference to FIGS. 1 to 16. Even after manufacturing, it is possible to provide a printed circuit board having reduced occurrence of warpage through the metal support layer 40 and the stiffener in the process of mounting the electronic component and bonding the solder ball.

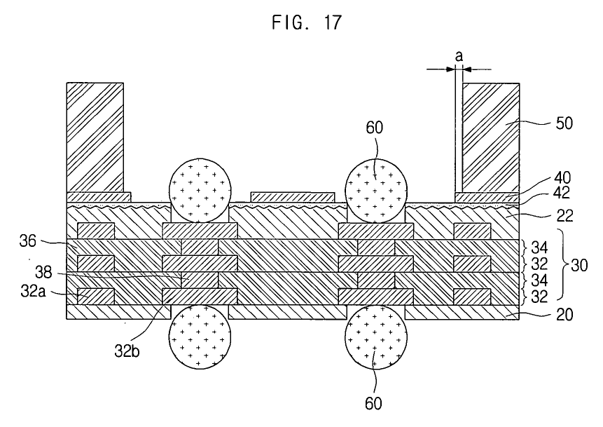

Hereinafter, a printed circuit board according to an embodiment of the present invention will be described with reference to FIG. 17.

According to an embodiment of the present invention, FIG. 17 shows a printed circuit board having an electronic component mounted thereon. Disclosed are a circuit laminate 30, solder resists 20 and 22 laminated on the circuit laminate, a metal support layer 40 formed on the solder resist and a stiffener 50 formed on the metal support layer.

The circuit laminate includes at least one circuit pattern layer 32 and at least one insulation layer 34. In other words, the circuit laminate 30 can be a multi-layer substrate made by laminating the circuit pattern layer and the insulation layer by turns.

According to an embodiment of the present invention, the first solder resist 20 is formed on one side of the circuit laminate. The first solder resist can be laminated on the one side of the circuit laminate 30, and the second solder resist 22 can be laminated on the other side of the circuit laminate.

The metal support layer 40 can be formed on the second solder resist. The metal support layer is formed on the second solder resist such that it provides rigidity to a coreless printed circuit board. According to the embodiment of the present invention, a stiffener 50 is formed on the metal support layer so that higher rigidity can be given to the printed circuit board.

The metal support layer 40 and the second solder resist 22 can be partly opened respectively in correspondence to the position of the electronic component to be mounted on the printed circuit board. The circuit pattern 32a or the pad 32b of the circuit laminate 30 can be exposed to the outside by opening a part of the metal support layer 40 and the second solder resist 22. A solder ball 60 is bonded to the exposed circuit pattern or pad. The electronic component is electrically connected to the printed circuit board through the solder ball.

As the second solder resist 22 is laminated on the other side of the circuit laminate 30, a part of the second solder resist 22 can be also opened. The circuit pattern 32a or the pad 32b can be exposed by opening a part of the second solder resist. The solder ball 60 is bonded to the exposed circuit pattern or pad. The printed circuit board can be electrically connected to an external substrate through the solder ball.

The stiffener 50 reinforces the rigidity of the coreless printed circuit board. As shown in FIG. 17, a part of the stiffener is opened in correspondence to the position of the electronic component to be mounted. The stiffener has a shape having an open part thereof. The electronic component can be mounted on the printed circuit board through the open parts of the stiffener, and can be connected to the circuit laminate through the solder ball 60.

While the stiffener has a open shape in a part thereof such that the electronic component is surrounded by the stiffener and mounted, the stiffener can have changeable and various shapes according to the intention of a designer and the position of the mounted electronic component.

The height of the upper surface of the stiffener 50 is configured to correspond to the height of the upper surface of the electronic component to be mounted. That is, it is beneficial to equalize the height of the upper side of the stiffener 50 formed on the metal support layer 40 and the height of the upper side of the electronic component mounted on the coreless printed circuit board. If the upper surface of the stiffener has the same height as that of the upper surface of the electronic component, provided is a very advantageous structure for manufacturing a metal heat spreader to be later installed for a heat release effect. Accordingly, the thickness of the stiffener can be changed according to the thickness of the electronic component to be mounted.

For example, if the electronic component has a thickness of 500 um, the metal support layer 40 is allowed to have a thickness of from 25 to 50 um and the stiffener 50 is allowed to have a thickness of from 475 to 500 um, so that a heat spreader process to be later made can be easy to perform.

As described in the manufacturing process of the printed circuit board according to an embodiment of the present invention, the stiffener 50 can be made of a material including a metallic material, and can be made of a metallic material same as the material of the metal support layer 40 which is formed through an electrolytic plating process.

According to an embodiment of the present invention, the material of the stiffener 50 can be either copper like the metal support layer 40 or other metals such as SUS and Ni. As described above, the stiffener 50 can be formed on the metal support layer through the ultrasonic bonding method.

For a structure in which the warpage is prone to occur like the coreless printed circuit board, the warpage of the product can be prevented by using the stiffener 50 having rigidity. After the stiffener is bonded, it is possible to provide a stable coreless printed circuit board that has low warpage even during a thermal process (IR reflow process) of several times, which is performed by a user of the printed circuit board.

The stiffener 50 can consider a position tolerance represented by a reference numeral of “a” occurring during the bonding process and cover a part of the metal support layer 40. In order to bond the stiffener 50 to the metal support layer, a force is given between the stiffener and the metal support layer by using the horn of the ultrasonic bonding apparatus under the ultrasonic condition of an ultrasonic bonding apparatus. Because a bonding method through a physical interference between metal structures in accordance with a right and left vibration is employed, a bonding position tolerance of 50 um may locally occur. Therefore, when bonding the stiffener 50 to the metal support layer 40 as shown in FIG. 17 in consideration of the tolerance above, work efficiency can be improved by assigning a value more than 50 um to the position tolerance.

In short, through the printed circuit board and the manufacturing method thereof in accordance with an embodiment of the present invention, it is possible to provide a printed circuit board that has low warpage of its own and strength against the warpage during the package process by using the metal support layer and the stiffener. Besides, the metal support layer and the stiffener have a superb bonding reliability.

While certain embodiment of the present invention has been described, it shall be understood by those skilled in the art that various changes and modification in forms and details may be made without departing from the spirit and scope of the present invention as defined by the appended claims.

Numerous embodiments other than embodiments described above are included within the scope of the present invention.

What is claimed is:

1. A method of manufacturing a printed circuit board, the method comprising:
forming a first solder resist;
forming a circuit laminate on the first solder resist;
forming a second solder resist on the circuit laminate;
forming a metal support layer on the second solder resist; and
forming a stiffener on the metal support layer.

2. The method of claim 1, further comprising, before the forming of the first solder resist, providing a carrier, wherein the first solder resist is formed on one side or both sides of the carrier.

3. The method of claim 2, further comprising, after the forming of the metal support layer on the second solder resist, separating the first solder resist, the circuit laminate, the second solder resist and the metal support layer from the carrier.

4. The method of claim 3, wherein the separating of the first solder resist, the circuit laminate, the second solder resist and the metal support layer from the carrier is performed by cutting a part of the first solder resist, the circuit laminate, the second solder resist and the metal support layer through a routing process.

5. The method of claim 1, wherein the circuit laminate comprises a circuit pattern layer and an insulation layer.

6. The method of claim 1, wherein the stiffener is made of a metallic material, and wherein the forming of the stiffener on the metal support layer is performed by bonding the stiffener to the metal support layer through an ultrasonic bonding method.

7. The method of claim 1, wherein the forming of the metal support layer on the second solder resist comprises:
forming a seed layer on the second solder resist through electroless plating; and
forming a conductive material on the seed layer through electrolytic plating.

8. The method of claim 7, wherein the forming of the metal support layer on the second solder resist further comprises, before the forming of the seed layer on the second solder resist, forming roughness on the surface of the second solder resist.

9. The method of claim 1, further comprising, after the forming of the metal support layer on the second solder resist, selectively removing a part of the metal support layer.

10. The method of claim 9, wherein the selectively removing of a part of the metal support layer comprises:
laminating a photosensitive material on the metal support layer;
forming an etching resist on the metal support layer by selectively exposing the photosensitive material to light and developing the photosensitive material; and
etching the metal support layer.

11. The method of claim 2, wherein the carrier comprises:
a substrate; and
a separation layer covering a part of the substrate.

12. The method of claim 11, wherein the substrate is a metal laminated plate.

13. The method of claim 11, wherein the separation layer is made of a material comprising a release material.

14. The method of claim 1, further comprising, after the separating of the first solder resist, the circuit laminate, the second solder resist and the metal support layer from the carrier:
selectively opening the first solder resist and the second solder resist; and
bonding a solder ball to the circuit laminate exposed by opening the first solder resist and the second solder resist.

15. The method of claim 14, wherein the selectively opening of the first solder resist and the second solder resist is performed by irradiating a laser beam to a part of the first solder resist and the second solder resist.

16. A printed circuit board having an electronic component mounted thereon, the printed circuit board comprising:
a circuit laminate;
a solder resist laminated on the circuit laminate;
a metal support layer formed on the solder resist; and
a stiffener formed on the metal support layer.

17. The printed circuit board of claim 16, wherein the circuit laminate comprises a circuit pattern layer and an insulation layer.

18. The printed circuit board of claim 16, wherein the solder resist comprises:
a first solder resist laminated on one side of the circuit laminate; and
a second solder resist laminated on the other side of the circuit laminate.

19. The printed circuit board of claim 18, wherein the metal support layer is formed on the second solder resist.

20. The printed circuit board of claim 16, wherein the stiffener is made of a material comprising a metallic material.

21. The printed circuit board of claim 16, wherein the stiffener is bonded to the metal support layer by performing an ultrasonic bonding method.

22. The printed circuit board of claim 16, wherein a part of the stiffener is opened in correspondence to a position where the electronic component is to be mounted.

23. The printed circuit board of claim 16, wherein a part of the metal support layer and a part of the solder resist are opened in correspondence to a position where the electronic component is to be mounted.

24. The printed circuit board of claim 16, wherein a height of an upper surface of the stiffener corresponds to a height of an upper surface of the electronic component.

25. The printed circuit board of claim 16, wherein the stiffener covers a part of the metal support layer.

26. The printed circuit board of claim 16, wherein the circuit laminate is electronically connected to the electronic component through a solder ball bonded to the circuit laminate.
